(19) United States
(12) Patent Application Publication
(10) Pub. No.: US 2026/0229270 A1
(43) Pub. Date: Aug. 6, 2026

(54) Self-Refresh Status Indication for Self-Refresh Exit

(71) Applicant: Micron Technology, Inc., Boise, ID (US)

(72) Inventors: Yang Lu, Boise, ID (US); HyunYoo Lee, Boise, ID (US); Kang-Yong Kim, Boise, ID (US)

(73) Assignee: Micron Technology, Inc., Boise, ID (US)

(21) Appl. No.: 19/045,465

(22) Filed: Feb. 4, 2025

(51) Int. Cl. G11C 11/406

(52) U.S. Cl. CPC G11C 11/40615; G11C 11/40603; G11C 11/40618

(57) ABSTRACT

Apparatuses and techniques for implementing self-refresh status indications for self-refresh exit are described. To save power, a memory device can control refresh operations, but the memory device is typically unavailable in this self-refresh mode. During self-refresh exiting, the memory device typically remains unavailable for normal array access operations while concluding any refresh operations that are already in progress. Portions of the memory array, however, are usually not performing a refresh operation. To enable a host device to perform read and write operations on these available portions during the self-refresh exit time, the memory device provides an indication of a self-refresh status in example implementations. The indication can be a Boolean variable that pertains to an entire array. Alternatively, the indication can include multiple bits that respectively correspond to multiple portions, such as memory banks or bank groups. In this way, the host device can return to normal operations sooner.

### BACKGROUND

Computers, smartphones, and other electronic devices rely on processors and memories. A processor executes code based on data to run applications and provide features to a user. The processor obtains the code and the data from a memory. The memory in an electronic device can include volatile memory (e.g., random-access memory (RAM)) and nonvolatile memory (e.g., flash memory). Like the capabilities of a processor, the capabilities of a memory can impact the performance of an electronic device. This performance impact can increase as processors are developed that execute code faster and as applications operate on increasingly larger data sets that require ever-larger memories.

### BRIEF DESCRIPTION OF THE DRAWINGS

Apparatuses and techniques for implementing self-refresh status indication for self-refresh exit are described with reference to the following drawings. The same numbers are used throughout the drawings to reference like features and components:

FIG. 1 illustrates example apparatuses that can implement aspects of self-refresh status indication for self-refresh exit;

FIG. 2 illustrates an example computing system that can implement aspects of self-refresh status indication for self-refresh exit with respect to a memory device;

FIG. 3 illustrates an example memory device with multiple memory banks and refresh logic with which aspects of self-refresh status indication for self-refresh exit may be implemented;

FIG. 4 depicts a first timing diagram and a second timing diagram that illustrate example exit schemes from a self-refresh mode in which a memory device does not provide a self-refresh status indication and in which a memory device does provide a self-refresh status indication, respectively;

FIG. 5 illustrates a schematic diagram of example communication schemes between a host device and a memory device for self-refresh status indication for self-refresh exit;

FIG. 6 is a relational diagram illustrating example implementations for a memory device to provide a self-refresh status indication to a host device;

FIGS. 7-1 and 7-2 depict a first timing diagram and a second timing diagram that illustrate example exit schemes from a self-refresh mode in which a memory device provides a Boolean self-refresh status indication for which a refresh operation is in progress and for which a refresh operation is not in progress, respectively;

FIG. 8 depicts a timing diagram that illustrates example exit schemes from a self-refresh mode in which a memory device provides a bank-specific self-refresh status indication based on a self-refresh exit command;

FIG. 9 depicts a timing diagram that illustrates example exit schemes from a self-refresh mode in which a memory device provides a bank-specific self-refresh status indication based on a self-refresh exit command and responsive to a mode-register read command requesting the indication;

FIG. 10 depicts a timing diagram that illustrates example exit schemes from a self-refresh mode in which a memory device provides a bank-specific self-refresh status indication based on a self-refresh exit command and responsive to a multi-purpose command (MPC) requesting the indication;

FIG. 11 illustrates example methods for implementing aspects of self-refresh status indication for self-refresh exit for a memory device; and

FIG. 12 illustrates example methods for implementing aspects of self-refresh status indication for self-refresh exit for a host device.

### DETAILED DESCRIPTION

### Overview

Computing devices provide various services for users of mobile devices and server devices. Some computing devices include a host device, which may include a memory controller, and a memory device for storing information. For some applications, such as portable electronic devices that operate on battery power and data centers that employ thousands of memory devices, reducing power usage by memory devices can provide appreciable improvements in energy efficiency. These applications may also benefit from increasing memory performance by reducing memory-access latency or periods of memory unavailability. Some implementations that are described herein can provide one or both advantages for a memory device or system, including for those having low-power memory types.

For example, double data rate synchronous dynamic random-access memory (DDR SDRAM), including low-power DDR (LPDDR) SDRAM, is a volatile memory. Volatile memory loses stored information if the power to the memory is not maintained. The memory cells of DRAM devices are typically made using pairs of capacitors and transistors. Information is stored using charge levels that are applied to the capacitors. This charge, however, gradually drains from the memory cells, so the data will eventually be lost if the capacitor is not recharged. Consequently, to maintain an appropriate charge that reflects the stored data, the memory cells are periodically refreshed.

The rate of charge leakage from each capacitor is generally known or can be predicted. Accordingly, the charge of each capacitor in the memory device can be repeatedly refreshed (e.g., periodically refreshed) sufficiently frequently to counteract this rate of charge loss at the capacitors. Generally, each memory cell in a volatile memory is refreshed within a DRAM retention time (e.g., approximately 64 milliseconds (ms)) to maintain the integrity of stored data. To perform a refresh operation, the memory reads data from a memory cell corresponding to a refresh address into a temporary storage buffer (e.g., a sense amp) and writes the data back to the memory cell with the proper “full” charge. A refresh address can include memory cell addresses, row addresses, bank addresses, and the like.

Refresh operations can be controlled in at least two ways. First, refresh operations may be initiated and controlled by a host device that is located external to the memory device. For instance, a memory controller can issue an auto-refresh command to a memory device. Second, refresh operations can be initiated, controlled, or otherwise performed internal to the memory device using a self-refresh operation. In an auto-refresh mode, the memory controller may issue a refresh command (e.g., an auto-refresh command) that corresponds to or includes one all-bank refresh (ABR) command or multiple per-bank refresh (PBR) commands, depending on the bank configuration. The memory controller can issue the refresh command at a frequency (e.g., at a refresh interval (tREF)) that is sufficient to refresh each memory cell within the DRAM retention time.

When a computing system or at least a memory subsystem is in a power-saving mode, the memory device can perform self-refresh operations at a similar rate or frequency as part of operating in a self-refresh mode. In the self-refresh mode, the memory device can control the timing and operations for refreshing rows of a DRAM array. The host device can therefore cease planning for, orchestrating, and communicating about memory refresh operations if the memory device is operating in a self-refresh mode.

The self-refresh mode can save power in a number of ways. For example, communications across an interconnect that couples a host device to a memory device can be paused. The interconnect therefore consumes less power. The respective interfaces to the interconnect, such as the driver circuits, at the host device and at the memory device can be at least partially powered down during a low-power mode to save additional power. Further, at the host device, a memory controller that controls interactions between a host processor of the host device and the memory device can be placed in a low-power mode.

The self-refresh mode for a memory device can therefore increase the power efficiency of a computing device. The self-refresh mode can also, however, decrease performance efficiency. For example, exiting the self-refresh mode can introduce a processing delay, or latency, in the execution of code by the host device. To exit the self-refresh mode, the host device sends a self-refresh exit (SRX) command to the memory device. A period of time transpires between when the memory device receives the self-refresh exit command and when the memory device is capable of responding to a memory access request, such as a memory read command or a memory write command. This time period is referred to as the self-refresh exit time (tXSR). The latency caused by the self-refresh exit time forces the host device to pause or stall before continuing to execute code. In other words, the host device must wait to perform useful functionality after determining that the low-power mode is to end and after commanding the memory device to exit the self-refresh mode.

In contrast with the forced latency described above, this document describes devices and techniques that enable the host device to restart accessing the memory device sooner after exiting a low-power mode. Described schemes and approaches appreciably reduce the average latency between when a host device issues a self-refresh exit command and when the host device can issue read and write memory access requests. Generally, in response to receiving a self-refresh exit command, a memory device can respond with an indication of a refresh operation status. The self-refresh-exit status indication can inform the host as to whether the worst-case timing delay is applicable. If the host device decodes the indication as representing that at least part of the DRAM is not busy with a refresh operation and is therefore available to perform normal read and write commands, the host device can start performing regular memory accesses without waiting for expiration of the full self-refresh exit time.

In example implementations, during a self-refresh mode, the memory device performs refresh operations on the DRAM at some average frequency over the DRAM retention time. Each refresh operation occupies a fraction of the DRAM retention time, but the memory device is not performing refresh operations during other portions of the retention time. During the DRAM retention time, there are therefore times when the memory device is not performing a refresh operation. If the self-refresh exit command is processed (e.g., received, decoded, or implemented) during one of the times that no refresh operation is being performed, the memory device can start performing normal read and write commands before expiration of the self-refresh exit time.

To enable the host device to utilize this opportunity, the memory device sends an indication of a refresh operation in relation to a memory bank of the multiple memory banks. More specifically, for this example, the indication can be realized as a Boolean indication that is indicative of whether the memory device has a refresh operation in progress. If the Boolean indication has a first value, the host device can access the memory device for standard read and write operations without waiting for the self-refresh exit time to transpire. On the other hand, if the Boolean indication has a second value, the host device waits for the self-refresh exit time to expire before sending a read or write command.

In other example implementations, memory devices include at least one memory array that are separated into multiple memory banks. During a self-refresh mode, the memory device may be performing a refresh operation in at least one memory bank but less than all memory banks of the multiple banks. A particular memory bank that is not undergoing a refresh operation can be available for accessing via regular read or write operations, even while another memory bank is undergoing a refresh operation. In such cases, the memory device can provide an indication that includes or otherwise serves as an identification of a subset of the multiple memory banks that has a refresh operation in progress (or that does not have a refresh operation in progress). Based on the identified subset of memory banks, the host device can command the memory device to perform a read or write command on one or more other banks that are not in the subset (or that are not in the subset) and that are not currently undergoing a refresh operation. Thus, even if a memory bank is being refreshed, the host device can continue executing code without waiting for expiration of the self-refresh exit time by accessing other memory banks.

In some implementations, the memory device can provide the indication by transmitting values over a data bus to a host device, such as to a memory controller thereof. In some cases, the memory device automatically transmits the indication based on the command to exit the self-refresh mode. The transmission can occur at a prescribed time or within a prescribed time period, such as one that is measured based on the self-refresh exit command. In other cases, the memory device refrains from sending the indication unless the host device requests the indication, such as by using a command that is separate from the self-refresh exit command. The host device can request the indication using, for example, a multipurpose command, a mode-register read command, and so forth. In response to receiving a request for the indication of whether a self-refresh operation is in progress, the memory device can transmit the indication to the host device. In any of these cases, the indication can be realized as a Boolean data value corresponding to all memory banks of a memory array or of the memory device or as multi-valued data corresponding to individualized memory banks or bank groups.

In these manners, by providing indications of refresh operations in relation to a memory bank based on a command to exit a self-refresh mode, the performance inefficiency of using the self-refresh mode to increase power efficiency can be appreciably reduced. For example, the inefficiency due to latency can be reduced by over fifty percent (50%). In some cases, the negative performance impact from using the self-refresh mode of a memory device can be reduced by over ninety percent (90%). Thus, implementing the schemes and techniques described herein can enable a computing device to achieve the power savings of using low-power modes that include a memory self-refresh mode while appreciably reducing the processing delays that otherwise result from exiting the self-refresh mode.

### Example Operating Environments

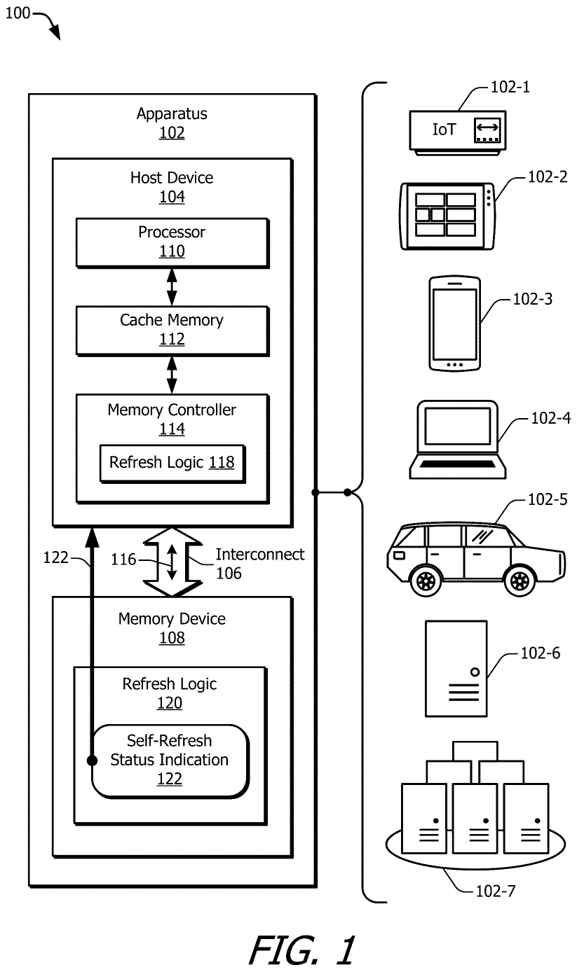

FIG. 1 illustrates, at 100 generally, an example operating environment including an apparatus 102 that can implement aspects of self-refresh status indication for self-refresh exit. The apparatus 102 can include various types of electronic devices, including an internet-of-things (IoT) device 102-1, a tablet device 102-2, a smartphone 102-3, a notebook computer 102-4, a passenger vehicle 102-5, a server computer 102-6, or a server cluster 102-7. The server computer 102-6 or the server cluster 102-7 may be part of cloud computing infrastructure, a data center, or a portion thereof (e.g., a printed circuit board (PCB)). Other examples of the apparatus 102 include a wearable device (e.g., a smartwatch or intelligent glasses), entertainment device (e.g., a set-top box, video dongle, smart television, a gaming device), desktop computer, motherboard, server blade, consumer appliance, vehicle, drone, industrial equipment, security device, sensor, medical device, or the electronic components of any computing device. Each type of apparatus can include one or more components to provide computing functionalities or features.

In example implementations, the apparatus 102 can include at least one host device 104, at least one interconnect 106, and at least one memory device 108. The host device 104 can include at least one processor 110, at least one cache memory 112, and at least one memory controller 114. The memory device 108, which can also be realized with a memory module, can include, for example, a dynamic random-access memory (DRAM) die or module (e.g., Low-Power Double Data Rate synchronous DRAM (LPDDR SDRAM)). The DRAM die or module can include a three-dimensional (3D) stacked DRAM device, which may be a high-bandwidth memory (HBM) device or a hybrid memory cube (HMC) device. The memory device 108 can operate as a main memory for the apparatus 102. Although not illustrated, the apparatus 102 can also include storage memory. The storage memory can include, for example, a storage-class memory device (e.g., flash memory, hard disk drive, solid-state drive, phase-change memory (PCM), or memory employing 3D XPoint™).

The processor 110 is operatively coupled to the cache memory 112, which is operatively coupled to the memory controller 114. The processor 110 is also coupled, directly or indirectly, to the memory controller 114. The host device 104 may include other components to form, for instance, a system-on-a-chip (SoC). The processor 110 may include a general-purpose processor, a central processing unit (CPU), a graphics processing unit (GPU), a neural network engine or accelerator, an application-specific integrated circuit (ASIC), a field-programmable gate array (FPGA) integrated circuit (IC), a communications processor (e.g., a modem or baseband processor), and so forth.

In operation, the memory controller 114 can provide a high-level or logical interface between the processor 110 and at least one memory (e.g., an external memory). The memory controller 114 may be realized with any of a variety of suitable memory controllers (e.g., a double-data-rate (DDR) memory controller that can process requests for data stored on the memory device 108). Although not shown, the host device 104 may include a physical interface (PHY) that transfers data between the memory controller 114 and the memory device 108 through the interconnect 106. For example, the physical interface may be an interface that is compatible with a DDR PHY Interface (DFI) Group interface protocol. The memory controller 114 can, for example, receive memory requests from the processor 110 and provide the memory requests to external memory with appropriate formatting, timing, and reordering. The memory controller 114 can also forward to the processor 110 responses to the memory requests that are received from the external memory.

The host device 104 is operatively coupled, via the interconnect 106, to the memory device 108. In some examples, the memory device 108 is connected to the host device 104 via the interconnect 106 with an intervening buffer or cache. The memory device 108 may be operatively coupled to storage memory (not shown). The host device 104 can also be coupled, directly or indirectly via the interconnect 106, to the memory device 108 and the storage memory. The interconnect 106 and other interconnects (not illustrated in FIG. 1) can transfer information between two or more components of the apparatus 102. Examples of the interconnect 106 include a bus (e.g., a unidirectional or bidirectional bus), a switching fabric, or one or more wires that carry voltage-based or current-based signals. The interconnect 106 can propagate one or more communications 116, such as memory requests or memory responses, between the host device 104 and the memory device 108. For example, the host device 104 may transmit a memory request to the memory device 108 over the interconnect 106. Also, the memory device 108 may transmit a corresponding memory response to the host device 104 over the interconnect 106.

In other implementations, the interconnect 106 can be realized as a Compute Express Link® (CXL®) protocol link (CXL link). In other words, the interconnect 106 can comport with at least one CXL standard or protocol. The CXL link can provide an interface on top of the physical layer and electricals of a Peripheral Component Interconnect Express (PCIe) 5.0 physical layer, for instance. The CXL link can cause requests to and responses from the memory device 108 to be packaged as flits. In still other implementations, the interconnect 106 can be another type of link, including a PCIe 5.0 link. In this document, some terminology may draw from one or more identified standards or versions thereof, like a CXL standard or an LPDDR5 standard, for clarity. The described principles, however, are also applicable to memories and systems that comport with other memory and bus standards and other types of interconnects.

The illustrated components of the apparatus 102 represent an example architecture with a hierarchical memory system. A hierarchical memory system may include memories at different levels, with each level having memory with a different speed or capacity. As illustrated, the cache memory 112 logically couples the processor 110 to the memory device 108. In the illustrated implementation, the cache memory 112 is at a higher level than the memory device 108. A storage memory, in turn, can be at a lower level than the main memory (e.g., lower than a level of the memory device 108). Memory at lower hierarchical levels may have a decreased speed but increased capacity relative to memory at higher hierarchical levels. Memory at lower hierarchical levels may also have a lower cost per bit.

The apparatus 102 can be implemented in various manners with more, fewer, or different components. For example, the host device 104 may include multiple cache memories (e.g., including multiple levels of cache memory) or no cache memory. In other implementations, the host device 104 may omit the processor 110 or the memory controller 114. A memory (e.g., the memory device 108) may have an “internal” or “local” cache memory (not shown in FIG. 1). As another example, the apparatus 102 may include cache memory between the interconnect 106 and the memory device 108. Computer engineers can also include any of the described or illustrated components in distributed or shared memory systems.

This document describes with reference to FIG. 1 an example computing device or system architecture having at least one host device 104 coupled to a memory device 108. Computer engineers may implement the host device 104 and the various memories in multiple manners. In some cases, the host device 104 and the memory device 108 may be realized with separate packages that can be disposed on, or physically supported by, a printed circuit board (e.g., a rigid or flexible motherboard). The host device 104 and the memory device 108 may alternatively be integrated together on an integrated circuit or fabricated on separate integrated circuits and packaged together. The memory device 108 may also be coupled to multiple host devices 104 via one or more interconnects 106 and may respond to memory requests from two or more host devices 104. In such cases, each host device 104 may include a respective memory controller 114, or the multiple host devices 104 may share a memory controller 114.

Two or more memory components (e.g., modules, packages, dies, bank groups, or banks) can share the electrical paths or couplings of the interconnect 106. In some cases, the interconnect 106 can include at least one command-and-address bus (CA bus) and at least one data bus (DQ bus). The command-and-address bus can transmit addresses and commands from the memory controller 114 of the host device 104 to the memory device 108, and this bus may exclude propagation of data. The data bus can propagate data bidirectionally between the memory controller 114 and the memory device 108. The memory device 108 may also be implemented as any suitable memory including, but not limited to, DRAM, SDRAM, three-dimensional (3D) stacked DRAM, DDR memory, or LPDDR memory (e.g., LPDDR DRAM or LPDDR SDRAM). Other examples of realizations for at least the memory device 108 include computational storage apparatuses, such as Computational Storage Devices (CSXs), Computational Storage Processors (CSPs), Computational Storage Drives (CSDs), and Computational Storage Arrays (CSAs). The memory device 108 may also include or be realized as processor-in-memory (PIM).

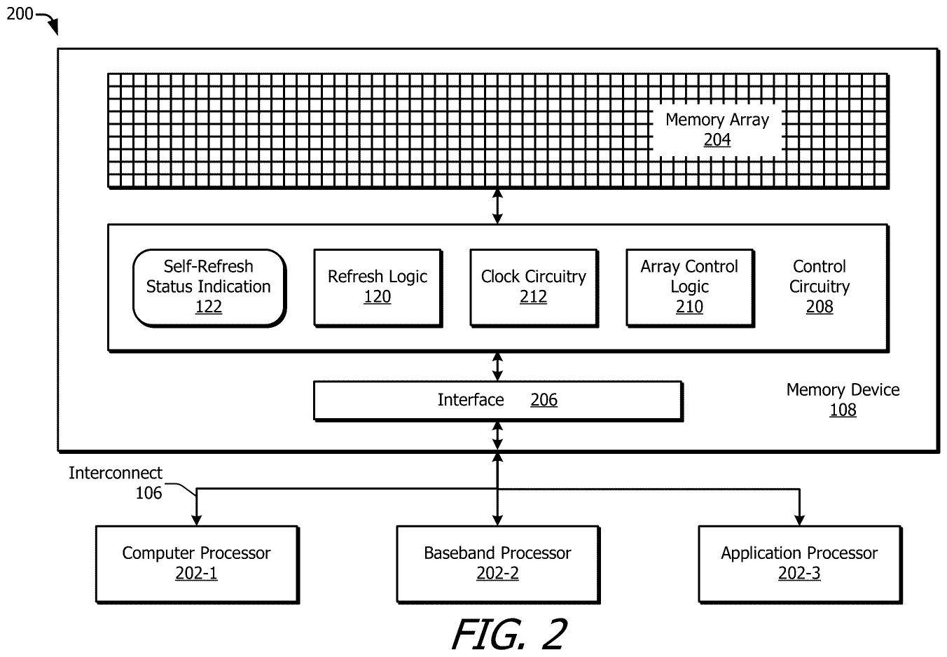

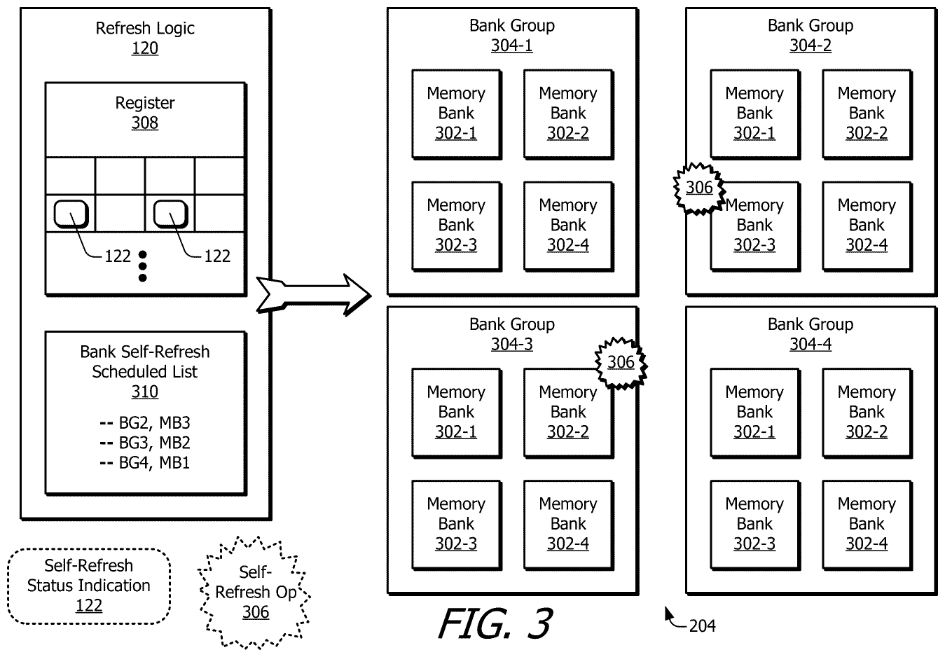

The memory device 108 can form at least part of the main memory of the apparatus 102. The memory device 108 may, however, form at least part of a cache memory, a storage memory, or a system-on-chip of the apparatus 102. The memory device 108 can include at least one memory array (e.g., as shown in FIGS. 2 and 3) and at least one instance of refresh logic 120. The host device 104 can include at least one instance of refresh logic 118. For instance, the memory controller 114 of the host device 104 can include the refresh logic 118. The refresh logic 118 individually, the refresh logic 120 individually, or the refresh logic 118 in combination with the refresh logic 120 can realize or perform one or more implementations for self-refresh status indications for self-refresh exit as described herein. In some implementations, the refresh logic 118 or the refresh logic 120 can be realized using circuitry, such as digital circuitry. Generally, the refresh logic 118 and the refresh logic 120, either separately or in combination with each other, can cause the memory device 108 to selectively provide a self-refresh status indication 122.

In example implementations, a self-refresh status indication 122 enables a host device 104 to begin making normal read and write requests to the memory device 108 sooner after commanding the memory device 108 to exit a self-refresh mode as compared to operating in an environment that lacks self-refresh status indications. The refresh logic 120 can store, generate, maintain, or otherwise include at least one self-refresh status indication 122. The self-refresh status indication 122 can indicate whether at least one portion of a memory array of the memory device 108 is performing or is not performing a refresh operation relative to a time period associated with the self-refresh exit. The self-refresh status indication 122 can be realized as a Boolean indication across a memory array or as a multi-bit indication that corresponds to or identifies one or more portions of the memory array.

The memory device 108 can provide the self-refresh status indication 122 to the host device 104 over the interconnect 106. For instance, the refresh logic 120 can provide the self-refresh status indication 122 with at least one communication 116 that is propagated over a data bus of the interconnect 106. The host device 104, such as the memory controller 114 thereof, can receive the self-refresh status indication 122 from the memory device 108 via the interconnect 106. For instance, the refresh logic 118 can receive the self-refresh status indication 122. If the self-refresh status indication 122 reveals that at least a portion of the memory array of the memory device 108 is not involved in a refresh operation, the refresh logic 118 can begin issuing normal read and write commands directed to that portion of the memory array before expiration of a self-refresh exit time. In these manners, memory access latency and idle periods of the processor can be reduced while still utilizing a self-refresh mode of the memory device that provides energy efficiency.

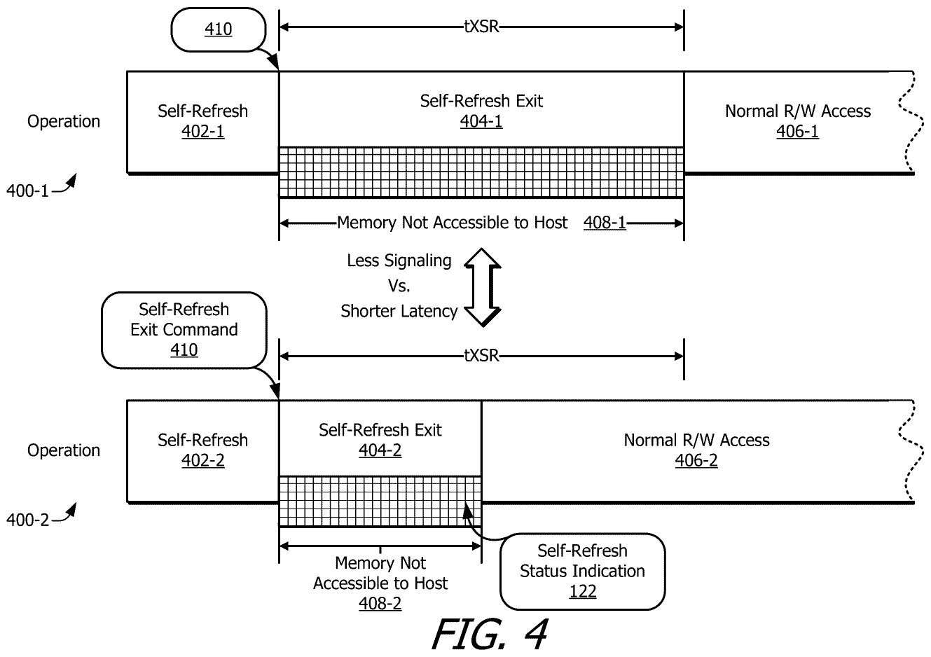

With reference to the two timing diagrams of FIG. 4, this document describes an example of how providing a self-refresh status indication 122 can accelerate the return of normal read/write access to a memory after a self-refresh mode is terminated. Prior to that description, examples are described below with reference to FIG. 3 of memory architectures for a memory device 108 in which at least one memory array is separated into bank groups and memory banks. In some cases, refresh operations may be performed independently or simultaneously in two or more different memory banks. Tracking the existence or progress of one or more refresh operations across one or more memory banks is also described with reference to FIG. 3. Next, however, this document describes examples of the memory device 108 with reference to FIG. 2.

FIG. 2 illustrates an example computing system 200 that can implement aspects of self-refresh status indication for self-refresh exit with respect to a memory device 108. In some implementations, the computing system 200 includes at least one memory device 108, at least one interconnect 106, and at least one processor 202. The memory device 108 can include, or be associated with, at least one memory array 204, at least one interface 206, and control circuitry 208 (or periphery circuitry) that is operatively coupled to the memory array 204. The memory array 204 can include an array of memory cells, including but not limited to memory cells of DRAM, SDRAM, three-dimensional (3D) stacked DRAM, DDR memory, LPDDR SDRAM, and so forth. The memory array 204 and the control circuitry 208 may be components on a single semiconductor die or on separate semiconductor dies. The memory array 204 or the control circuitry 208 may also be distributed across multiple dies. The control circuitry 208 may manage traffic on a bus that is separate from the interconnect 106, such as an internal bus of the memory device 108.

The control circuitry 208 can include various components that the memory device 108 can use to perform various operations. These operations can include communicating with other devices, managing memory performance, performing refresh operations (e.g., self-refresh operations or auto-refresh operations for DRAM), and performing memory read or write operations. For example, the control circuitry 208 can include at least one instance of array control logic 210, clock circuitry 212, and refresh logic 120. The array control logic 210 can include circuitry that provides command decoding, address decoding, input/output functions, amplification circuitry, power supply management, power control modes, sense amplifying for data retrieval operations, write driving for data storage operations, and other functions.

The clock circuitry 212 can synchronize various memory components with one or more external clock signals provided over the interconnect 106, including a command-and-address clock or a data clock. The clock circuitry 212 can also or instead use an internal clock signal to synchronize memory components, and the clock circuitry 212 may provide timer functionality, such as for self-refresh operations. The refresh logic 120 can perform refresh operations on the memory array 204 (e.g., if the memory array 204 includes DRAM cells) in a self-refresh mode or an auto-refresh mode. The refresh logic 120 can also perform at least part of the memory-device-side operations for providing self-refresh status indications for self-refresh exits as described herein. Although not explicitly shown in FIG. 2, the control circuitry 208 may include one or more mode registers to facilitate control by and/or communication with a processor 202. By way of example, at least one self-refresh status indication 122 can be stored in one or more mode registers.

The interface 206 can couple the control circuitry 208 or the memory array 204 directly or indirectly to the interconnect 106. In some implementations, the array control logic 210, the clock circuitry 212, and the refresh logic 120 can be part of a single component (e.g., the control circuitry 208). In other implementations, one or more of the array control logic 210, the clock circuitry 212, or the refresh logic 120 may be implemented as separate components, which can be provided on a single semiconductor die or disposed across multiple semiconductor dies. These components may individually or jointly couple to the interconnect 106 via the interface 206.

The interconnect 106 may use one or more of a variety of interconnects that communicatively couple together various components and enable commands, addresses, or other information and data to be transferred between two or more components (e.g., between the memory device 108 and a processor 202). Although the interconnect 106 is illustrated with a single line in FIG. 2, the interconnect 106 may include at least one bus, at least one switching fabric, one or more wires or traces that carry voltage or current signals, at least one switch, one or more buffers, and so forth. Further, the interconnect 106 may be separated into at least a command-and-address bus and a data bus. Also, as discussed above with respect to FIG. 1, the interconnect 106 can include a CXL link or comport with at least one CXL standard. The CXL link can provide an interface or overlay on top of the physical layer and electricals of, e.g., a PCIe 5.0 physical layer.

In some aspects, the memory device 108 may be a “separate” component relative to the host device 104 (of FIG. 1) or any of the processors 202. The separate components can include a printed circuit board (PCB), memory card, memory stick, or memory module (e.g., a single in-line memory module (SIMM), dual in-line memory module (DIMM), or CXL memory module). Separate physical components may be located together within the same housing of an electronic device or may be distributed over a server rack, a data center, and so forth. Alternatively, the memory device 108 may be integrated with other physical components, including the host device 104 or the processor 202, by being combined together on a printed circuit board, in a single package, or in a system-on-chip (SoC).

As shown in FIG. 2, the one or more processors 202 may include a computer processor 202-1, a baseband processor 202-2, and/or an application processor 202-3 that are coupled to the memory device 108 through the interconnect 106. The processors 202 may include or form a part of a central processing unit (CPU), graphics processing unit (GPU), system-on-chip (SoC), application-specific integrated circuit (ASIC), or field-programmable gate array (FPGA). In some cases, a single processor can comprise multiple processing resources or cores, each dedicated to different functions (e.g., modem management, applications, graphics, security, artificial intelligence (AI), or central processing). In some implementations, the baseband processor 202-2 may include or be coupled to a modem (not illustrated in FIG. 2) and referred to as a modem processor. The modem or the baseband processor 202-2 may be coupled wirelessly to a network via, for example, cellular, Wi-Fi®, Bluetooth®, near field, or another technology or protocol for wireless communication.

In some implementations, the processors 202 may be connected directly to the memory device 108 (e.g., via the interconnect 106). In other implementations, one or more of the processors 202 may be indirectly connected to the memory device 108 (e.g., over a network connection or through one or more other devices). Further, the processor 202 may be realized as one that can communicate over a CXL-compatible interconnect. Accordingly, a respective processor 202 can include or be associated with a respective link controller. Alternatively, two or more processors 202 may access the memory device 108 using a shared link controller. In some of such cases, the memory device 108 may be implemented as a CXL-compatible memory device (e.g., as a CXL Type 3 memory expander), or another memory device that is compatible with a CXL protocol may also or instead be coupled to the interconnect 106.

### Example Techniques and Hardware

FIG. 3 illustrates an example memory device with multiple memory banks 302 and refresh logic 120 with which aspects of self-refresh status indication for self-refresh exit may be implemented. As shown, a memory array 204 can include multiple bank groups 304-1 to 304-Y (with “Y” representing an integer greater than one), such as four bank groups 304-1, 304-2, 304-3, and 304-4. Although four bank groups are shown and described herein, a memory device 108 or memory array 204 thereof can include more or fewer bank groups. Further, the memory device 108 and the memory array 204 may lack bank groups such that the multiple memory banks are not separated into different bank groups. As illustrated, each bank group 304 includes multiple memory banks 302-1 to 302-X (with “X” representing an integer greater than one), such as four memory banks 302-1, 302-2, 302-3, and 302-4. Although four memory banks 302 per bank group 304 are depicted in FIG. 3 and described herein, each bank group 304 may have more or fewer than four memory banks 302. Further, the memory array 204 may include more or fewer than 16 total memory banks 302, such as 8, 24, 32, 64, or more memory banks 302.

In example implementations, the refresh logic 120 can perform a refresh operation on one or more memory banks 302. The refresh operation can be an auto-refresh operation or a self-refresh operation 306. In some cases, the refresh logic 120 can perform multiple self-refresh operations 306 simultaneously or at least partially overlapping in time (e.g., with staggered start times). These overlapping self-refresh operations 306 can be performed in different memory banks 302, which can be part of the same or different bank groups. As shown in FIG. 3, by way of example only, the refresh logic 120 is performing a self-refresh operation 306 in the memory bank 302-3 of the bank group 304-2 (“BG2, MB3”) and another self-refresh operation 306 in the memory bank 302-2 of the bank group 304-3 (“BG3, MB2”).

The refresh logic 120 can provide (e.g., generate, track, maintain, or transmit) at least one self-refresh status indication 122 based on whether at least one self-refresh operation 306 is in progress. As described herein, the self-refresh status indication 122 may be a Boolean variable that is asserted (e.g., positive or a “1”) if any self-refresh operation 306 is in progress but unasserted (e.g., negative or a “0”) if no self-refresh operation 306 is in progress. Alternatively, the refresh logic 120 may provide a respective self-refresh status indication 122 for each respective memory bank 302 of the memory array 204. Each individual self-refresh status indication 122 may therefore be realized as an individual variable with respect to the corresponding individual memory bank 302. Thus, if the memory array 204 has sixteen memory banks 302, the refresh logic 120 may provide 16 per-bank self-refresh status indications 122.

In example implementations, the indication 122 of a refresh operation 306 is made in relation to a memory bank 302 of the multiple memory banks 302-1 to 302-X. The self-refresh status indication 122 includes an identification of a subset of the multiple memory banks 302-1 to 302-X, with the subset having the refresh operation 306 in progress. In some cases, the identification of the subset of the multiple memory banks 302-1 to 302-X that has the refresh operation 306 in progress includes at least one individual memory bank 302 of the multiple memory banks 302-1 to 302-X. In other cases, the identification of the subset of the multiple memory banks 302-1 to 302-X that has the refresh operation 306 in progress includes at least one individual bank group 304 of the multiple memory banks 302-1 to 302-X.

The refresh logic 120 may store the one or more self-refresh status indications 122 in one or more registers 308. The at least one register 308 may be exposed to external hardware. For example, the register 308 may be realized as a mode register that can be read by a host device. If multiple self-refresh status indications 122 are stored in multiple mode registers, a host device or memory controller may perform multiple read operations to access the multiple mode registers.

One or more registers 308 may be co-located with other registers that are not associated with refresh operations, such as in a bank of mode registers. In some implementations, the one or more registers 308 can include multiple bits that are configured to represent an identification of a subset of the multiple memory banks. For example, each respective bit of the multiple bits can correspond to a respective identification of a respective part (e.g., a memory bank 302 or a bank group 304) of the subset of the multiple memory banks. In example operations, the refresh logic can store a value in a bit of the multiple bits based on whether a refresh operation is in progress for the respective part of the subset of the multiple memory banks with regard to receipt of a command to exit the self-refresh mode.

In some implementations, the refresh logic 120 generates a bank self-refresh scheduled list 310. The bank self-refresh scheduled list 310 can include one or more memory banks 302 that are currently being refreshed (e.g., in-progress self-refresh operations) or that are being prepared to be refreshed (e.g., scheduled but still in-preparation). Banks that are in-preparation may be sufficiently far along in the process that canceling or preventing the self-refresh operation would entail more time, power, or complexity without accomplishing a refresh operation relative to simply permitting the self-refresh operation to be performed. Further, there may be a bank or associated self-refresh operation that is queued for scheduling but can be canceled due to the process being at an earlier stage. Thus, the self-refresh status indication 122 can, in some implementations, be indicative of memory banks that are already being prepared for a self-refresh operation 306 even though the self-refresh operation 306 has not actually started. In FIG. 3, the bank self-refresh scheduled list 310 includes three entries: BG2, MB3 (currently being refreshed); BG3, MB2 (currently being refreshed); and BG4, MB1 (in preparation for being refreshed). A bank self-refresh scheduled list 310 may, however, have more or fewer than three entries at any given time.

FIG. 4 depicts a first timing diagram 400-1 and a second timing diagram 400-2 that illustrate example exit schemes from a self-refresh mode in which a memory device does not provide a self-refresh status indication and in which a memory device does provide a self-refresh status indication, respectively. As illustrated, each timing diagram 400 includes multiple operations or operational phases: a self-refresh operational phase 402, a self-refresh exit operational phase 404, and a normal read/write access operational phase 406. With reference to the first timing diagram 400-1, the memory device is in the self-refresh operational phase 402-1 (e.g., a self-refresh mode) when the memory device receives a self-refresh exit command 410, such as from a memory controller. In response to the self-refresh exit command 410, the memory device transitions to the self-refresh exit operational phase 404-1.

The memory device is responsible for completing the self-refresh exit operational phase 404-1 within a self-refresh exit time (tXSR). The self-refresh exit time may be established by a memory standard. Additionally or alternatively, the self-refresh exit time may be variable or adjustable. During the self-refresh exit time, the memory device can perform any self-refresh operations that are in progress upon receipt of the self-refresh exit command 410 and/or otherwise complete operations that are part of the self-refresh mode. The memory device is expected to be prepared to accept normal read and write requests upon expiration of the self-refresh exit time. During the self-refresh exit time period, the memory device is not accessible to the host device, as indicated at 408-1 with the grid fill pattern, at least for normal read and write operations. Consequently, the host device cannot execute code that depends on new memory accesses, which can result in a processor stalling.

In accordance with the first timing diagram 400-1, the memory device omits providing a self-refresh status indication 122. The normal read/write access operational phase 406-1 can therefore not start until the end of a predetermined time period: the full self-refresh exit time. Thus, although this approach can be simpler and produce less signaling between the memory device and the host device, the processing latency is greater on average than for implementations in which a memory device does provide a self-refresh status indication for self-refresh exit operations.

With reference to the second timing diagram 400-2, the memory device is in the self-refresh operational phase 402-2 (e.g., a self-refresh mode) when the memory device receives a self-refresh exit command 410, such as from a memory controller. In response to the self-refresh exit command 410, the memory device transitions to the self-refresh exit operational phase 404-2. The memory device is still responsible for completing the self-refresh exit operational phase 404-2 within the self-refresh exit time (tXSR). However, the memory device may be ready to process normal read and write requests sooner. To enable the processor to take advantage of this early access, the memory device can signal the capability to process read and write requests sooner using at least one self-refresh status indication 122.

During the self-refresh exit time, the memory device can perform any self-refresh operations that are in progress upon receipt of the self-refresh exit command 410 and/or otherwise complete operations that are part of the self-refresh mode. During the self-refresh exit operational phase 404-2, the memory device is not accessible to the host device as indicated at 408-2 with the grid fill pattern. This period, however, can be shorter than the predetermined time period of tXSR—at least for a portion of a memory array—as communicated using the self-refresh status indication 122.

To make the period shorter, in response to processing (e.g., receiving, decoding, or processing) the self-refresh exit command 410, the memory device provides the self-refresh status indication 122. Multiple schemes for providing the self-refresh status indication 122 are described herein. These schemes can vary based on, for example, a timing of the communication, whether the host device explicitly requests the communication with an external command or the memory device provides it automatically, whether the indication is Boolean across a memory array or individualized on a per-bank basis. Thus, the memory device can communicate to the host device that the normal read/write access operational phase 406-2 can start before expiration of the self-refresh exit time. The earlier access may pertain to an entire memory array (e.g., with an array-wide Boolean indicator) or to selected memory banks (e.g., with multiple per-bank indicators). Consequently, the host device can execute code that depends on new memory accesses sooner due to the memory device providing the self-refresh status indication 122, which can result in a shorter latency period after a self-refresh mode is terminated.

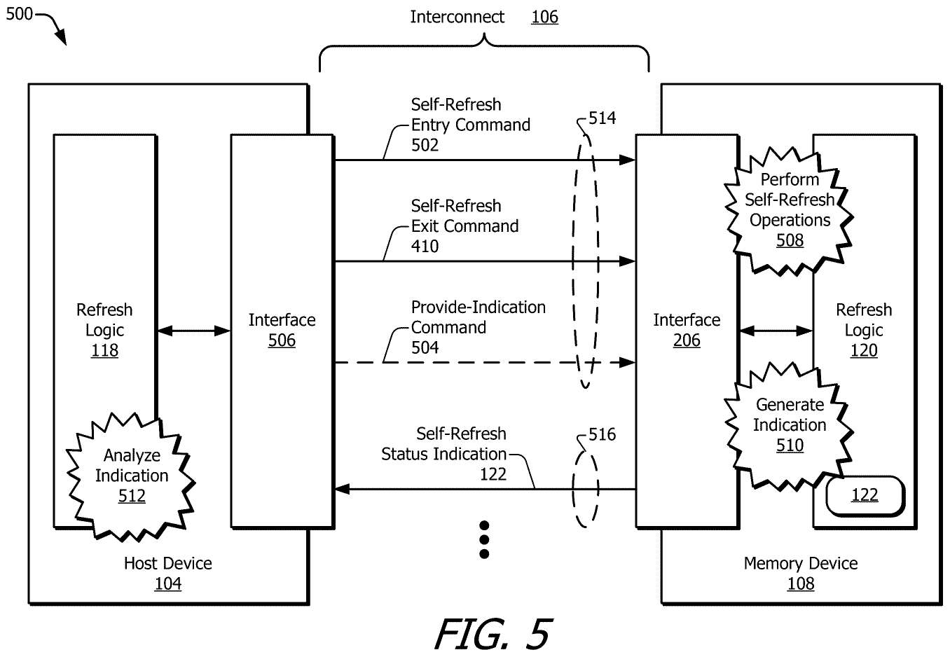

FIG. 5 illustrates a schematic diagram 500 of example communication schemes between a host device 104 and a memory device 108 for self-refresh status indication for self-refresh exit. As shown, the memory device 108 includes the interface 206 and the refresh logic 120. Thus, the memory device 108 can communicate with the host device 104 via the interconnect 106 using the interface 206. The host device 104 includes an interface 506 and the refresh logic 118. The host device 104 can communicate with the memory device 108 via the interconnect 106 using the interface 506.

More specifically, the interface 506 and the interface 206 can be coupled to the interconnect 106. The interface 506 of the host device 104 may be configured to be coupled to the memory device 108 via the interconnect 106. Similarly, the interface 206 of the memory device 108 may be configured to be coupled to the host device 104 via the interconnect 106. The refresh logic 120 is coupled to the interface 206, and the refresh logic 118 is coupled to the interface 506. Thus, the refresh logic 118 and the refresh logic 120 can exchange communications with each other over the interconnect 106.

Generally, the refresh logic 118 can perform functionality related to implementing self-refresh status indications with respect to self-refresh exit operations for the host device 104. Analogously, the refresh logic 120 can perform functionality related to implementing self-refresh status indications with respect to self-refresh exit operations for the memory device 108. The example commands, signals, actions, communications, and other operations depicted in FIG. 5 and described below may be implemented differently by way of sequence, omission, combination, and so forth in accordance with the circuitry or programming of a host device and/or a memory device.

In example implementations, the refresh logic 118 generates a self-refresh entry command 502. In some cases, the host device 104 determines to enter a low-power mode. Causing the memory device 108 to enter a self-refresh mode can support the low-power mode. The refresh logic 118 uses the interface 506 to transmit the self-refresh entry command 502 to the memory device 108 over the interconnect 106. The refresh logic 120 receives the self-refresh entry command 502 from the refresh logic 118 via the interconnect 106 using the interface 206. In response, the refresh logic 120 enters the self-refresh mode and performs multiple self-refresh operations at 508.

After some time period elapses, the refresh logic 118 generates a self-refresh exit command 410. In some cases, the host device 104 determines to exit the low-power mode. Causing the memory device 108 to exit the self-refresh mode reenables access to the memory. The refresh logic 118 uses the interface 506 to transmit the self-refresh exit command 410 to the memory device 108 over the interconnect 106. The refresh logic 120 receives the self-refresh exit command 410 from the refresh logic 118 via the interconnect 106 using the interface 206. In response, the refresh logic 120 starts exiting the self-refresh mode, which can include ceasing to schedule any new self-refresh operations and completing any self-refresh operations that are in progress when the self-refresh exit command 410 is processed.

Based on the self-refresh exit command 410, the refresh logic 120 generates at 510 a self-refresh status indication 122. The self-refresh status indication 122 may be generated based on data that the refresh logic 120 creates or maintains during self-refresh operations or may be generated from data that is obtained in response to receiving the self-refresh exit command 410. To enable the host device 104 to resume normal read and write operations before a full self-refresh exit time has elapsed, the self-refresh status indication 122 is communicated to the refresh logic 118. To do so, the refresh logic 120 uses the interface 206 to transmit the self-refresh status indication 122 to the host device 104 over the interconnect 106. The refresh logic 118 receives the self-refresh status indication 122 from the refresh logic 120 via the interconnect 106 using the interface 506. In response, the refresh logic 118 can analyze at 512 the self-refresh status indication 122 to determine if at least a portion of a memory array (e.g., at least one bank) can be accessed before expiration of the self-refresh exit time.

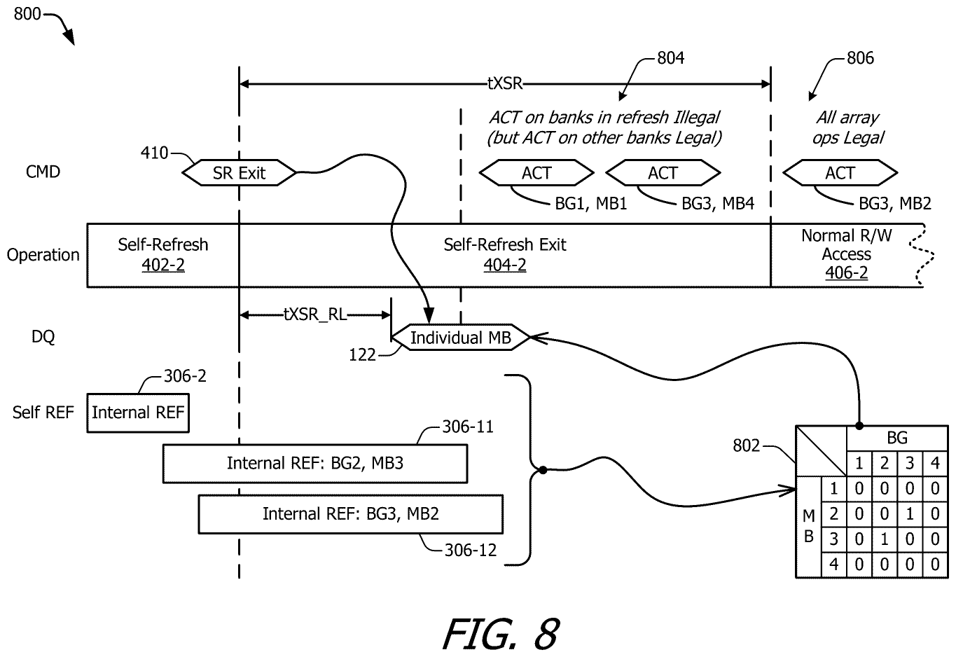

In some cases, the refresh logic 120 provides the self-refresh status indication 122 to the refresh logic 118 “automatically” based on receipt of the self-refresh exit command 410. Examples of this approach are described below with reference to FIG. 8. In other cases, the refresh logic 120 provides the self-refresh status indication 122 to the refresh logic 118 responsive to a request to provide the self-refresh status indication. Examples of this approach are described below with reference to FIGS. 7-1, 7-2, 9, and 10. Providing the indication automatically or in response to a separate request may be a selectable setting for the memory device 108. For example, the host device 104 can control, such as by writing to a mode register (e.g., by writing a value to the mode register to control the setting), whether the memory device 108 provides the indication automatically or only in response to a request for the indication.

With reference to FIG. 5, for devices or settings that utilize an indication-request mechanism, the refresh logic 118 uses the interface 506 to transmit a provide-indication command 504 to the memory device 108 over the interconnect 106. The refresh logic 120 receives the provide-indication command 504 from the refresh logic 118 via the interconnect 106 using the interface 206. The provide-indication command 504 may be implemented using, for example, a mode-register read (MRR) command, a multipurpose command (MPC), and so forth. In response to receiving the provide-indication command 504, the refresh logic 120 can generate at 510 the self-refresh status indication 122 and transmit the self-refresh status indication 122 to the refresh logic 118.

As described herein, the interconnect 106 can include a command-and-address bus 514 (CA bus 514) and a data bus 516 (DQ bus 516). In at least some of such cases, the self-refresh entry command 502, the self-refresh exit command 410, and the provide-indication command 504 can be propagated over the command-and-address bus 514. For example, the refresh logic 118 can transmit the self-refresh exit command 410 over the command-and-address bus 514, and the refresh logic 120 can receive the self-refresh exit command 410 via the command-and-address bus 514. Further, the self-refresh status indication 122 can be propagated over at least one data line of the data bus 516. For example, the refresh logic 120 can transmit the self-refresh status indication 122 over the data bus 516, and the refresh logic 118 can receive the self-refresh status indication 122 via the data bus 516.

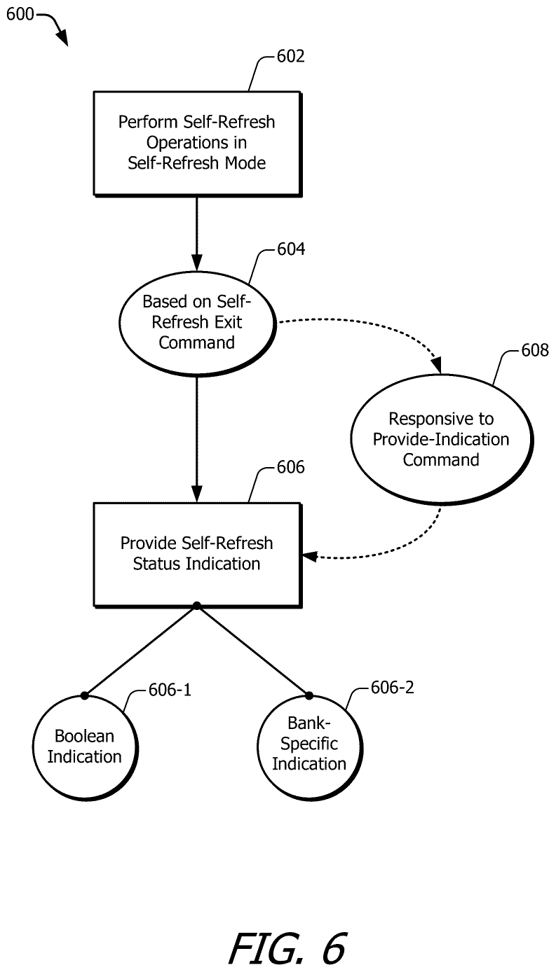

FIG. 6 is a relational diagram 600 illustrating example implementations for a memory device to provide a self-refresh status indication to a host device. As part of being in a self-refresh mode, the memory device performs self-refresh operations at 602. While in the self-refresh mode, the memory device receives a self-refresh exit command at 604. The memory device can receive the self-refresh exit command from, for instance, a memory controller. Based on the self-refresh exit command (as received at 604), the memory device provides a self-refresh status indication at 606. The self-refresh status indication can include a Boolean indication at 606-1 or a bank-specific indication at 606-2. Example scenarios that involve a Boolean indication are described below with reference to FIGS. 7-1 and 7-2. Example scenarios that involve a bank-specific indication are described below with reference to FIGS. 8-10.

Providing the self-refresh status indication at 606 can also be responsive to processing a provide-indication command at 608. In at least some of such cases, the providing of the self-refresh status indication (at 606) by the memory device may be contingent on receipt of the provide-indication command. In other words, in some implementations, the memory device does not transmit a self-refresh status indication to the host device until a provide-indication command is received. Example implementations that involve a command to provide the self-refresh status indication are described below with reference to FIGS. 7-1, 7-2, 9, and 10. Although the Boolean indication examples of FIGS. 7-1 and 7-2 are presented primarily in terms of scenarios that entail a request to provide the self-refresh status indication, Boolean indications may also be provided “automatically” without requiring receipt of, or waiting to receive, a provide-indication command.

FIGS. 7-1, 7-2, 8, 9, and 10 each depict a timing diagram related to self-refresh status indications that are provided in the context of a memory device that is exiting a self-refresh mode. Each timing diagram includes four rows: a command row (“CMD”), an operational phase row (“Operation”), a data bus row (“DQ”), and a self-refresh row (“Self REF”). The CMD row includes memory commands that a host device transmits to a memory device. The operational phase row has operational phases like those described above with reference to FIG. 4. These include a self-refresh operational phase 402-2, a self-refresh exit operational phase 404-2, and a normal read/write access operational phase 406-2. The DQ row includes values that the memory device transmits to the host device, such as at least one value representing at least part of a self-refresh status indication 122. The self-refresh row depicts whether and when an internally initiated refresh operation (“Internal REF”) is in progress.

FIGS. 7-1 and 7-2 depict a first timing diagram 700-1 and a second timing diagram 700-2 that illustrate example exit schemes from a self-refresh mode in which a memory device provides a Boolean self-refresh status indication for which a refresh operation is in progress and a Boolean self-refresh status indication for which a refresh operation is not in progress, respectively. Both timing diagrams depict the self-refresh exit time (tXSR) that extends from issuance of a self-refresh exit command (“SR Exit”) until all array operations are legal again at 706 regardless of the value of the self-refresh status indication 122.

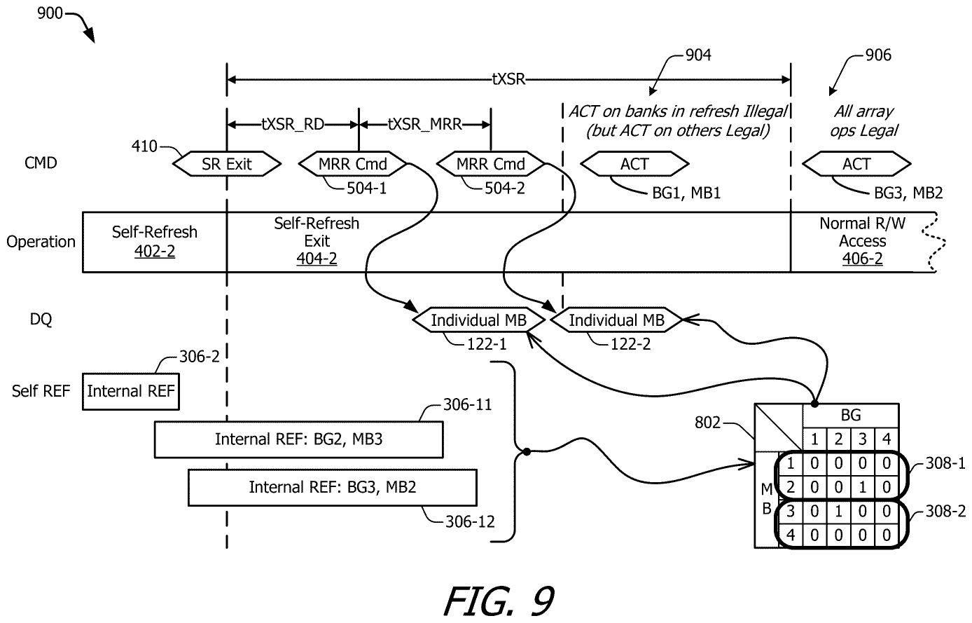

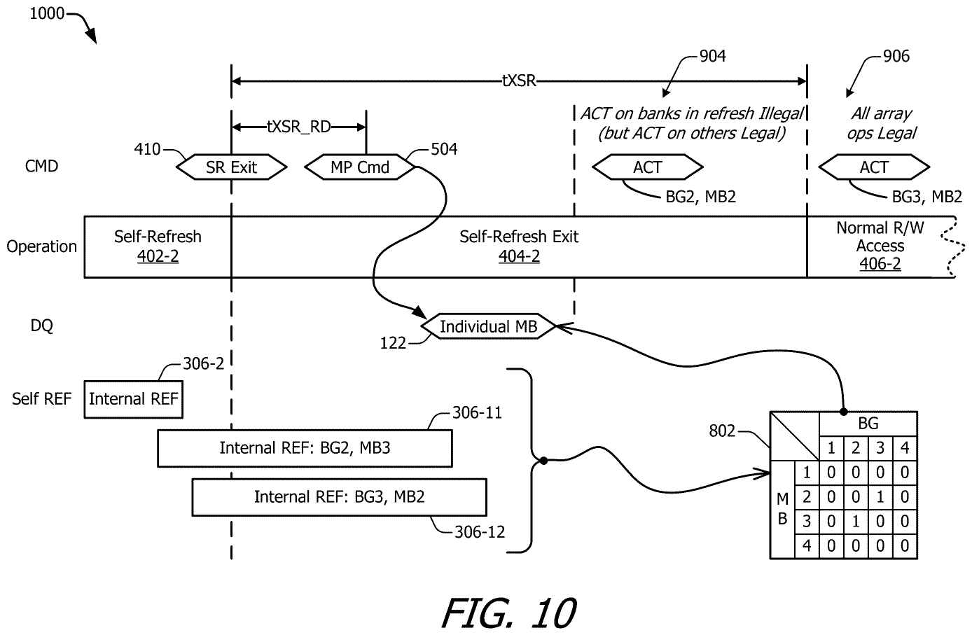

In example implementations for the timing diagram 700-1, the host device issues a request for a self-refresh status indication (“Request” 504), which is also referred to herein as a provide-indication command 504. In some cases, the host device issues the request with a read duration timing after the self-request exit command of “tXSR_RD.” As described below with reference to FIGS. 9 and 10, the request can be realized using a memory command such as a mode-register read (MRR) command or a multipurpose command (MPC). Alternatively, the request can be realized using a specialized or different type of command.

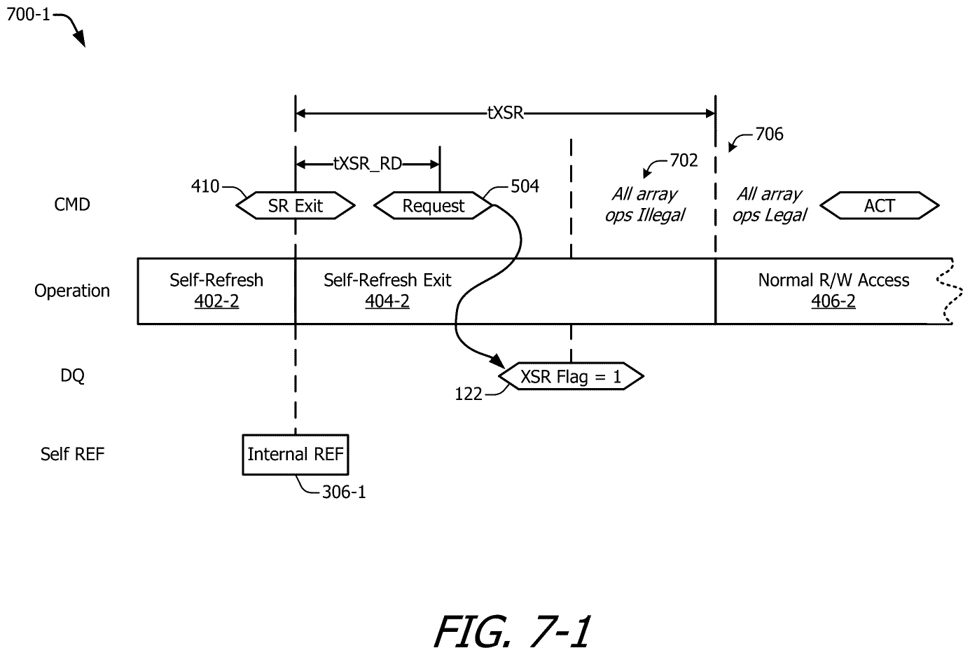

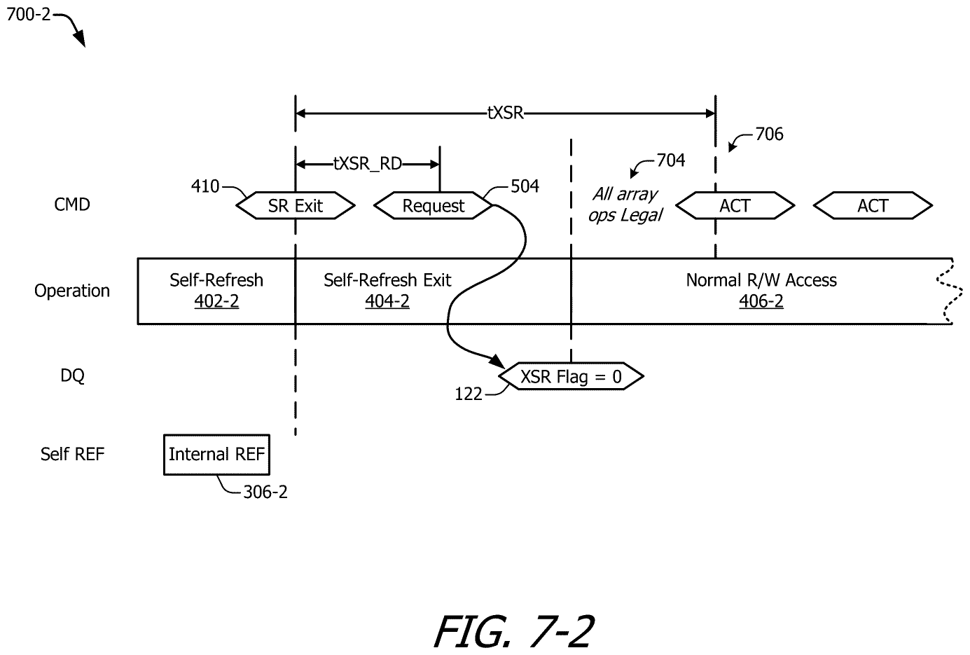

Responsive to receiving, and/or in conjunction with handling, the self-refresh exit command 410, the memory device can determine if a refresh operation is in progress with respect to the processing of the self-refresh exit command 410. For example, the memory device can determine if at least one refresh operation is in progress when the self-refresh exit command 410 is received, decoded, or starting to be performed. Due to the frequency of refresh operations and the length of each one, there are times when no refresh operation is in progress. This situation is described below with reference to FIG. 7-2.

For the first timing diagram 700-1 of FIG. 7-1, however, there is a refresh operation 306-1 that is in progress. Accordingly, the memory device generates a Boolean-type self-refresh status indication 122 that indicates that at least one refresh operation is progress. In FIG. 7-1, this indication is represented by an “XSR Flag” that equals “1.” This may be realized, for example, as one bit in a mode register, one bit on the DQ bus, and so forth. The memory device drives the self-refresh status indication 122 on the DQ bus for the host device to receive. Because the indication is Boolean and the indication is that at least one refresh operation is in progress, the host device can determine at 702 that all array operations are illegal until expiration of the self-refresh exit time.

For the second timing diagram 700-2 of FIG. 7-2, there is not a refresh operation in progress. Instead, the most-recent refresh operation 306-2 has concluded when the self-refresh exit command 410 is processed. Accordingly, the memory device generates a Boolean-type self-refresh status indication 122 that indicates that no refresh operation is progress. In FIG. 7-2, this indication is represented by an “XSR Flag” that equals “0.” This may be realized, for example, as one bit in a mode register, one bit on the DQ bus, and so forth. The memory device drives the self-refresh status indication 122 on the DQ bus for the host device to receive.

Because the indication is Boolean and the indication is that no refresh operation is in progress, the host device can determine at 704 that all array operations are legal, including before expiration of the self-refresh exit time at 704 as well as after at 706. The host device can therefore start sending normal read and write commands sooner (e.g., as represented by the activate command (“ACT”)) as compared to memory systems that lack self-refresh status indications for self-refresh exit scenarios. The various timing diagrams are not necessarily drawn to scale, so multiple activation commands may, in some cases, be sent by the host device before the self-refresh exit time expires if the negative self-refresh status indication 122 is transmitted sufficiently quickly. In these manners, a Boolean-type of self-refresh status indication 122 can reduce access latency when a memory system exits a power-saving self-refresh mode.

Although the Boolean indication examples of FIGS. 7-1 and 7-2 are presented in terms of scenarios that entail a request 504 to provide the self-refresh status indication 122, Boolean indications may also be provided “automatically” without requiring receipt of, or waiting to receive, a provide-indication command 504. An example of “automatically” providing the self-refresh status indication 122 without an external command that is separate from the self-refresh exit command 410 is described below with reference to FIG. 8.

At the cost of increased complexity or signaling, access latency can be reduced still further with a bank-specific-type of self-refresh status indication. With Boolean indications, the host device does not start normal read and write accesses until expiration of the self-refresh exit time if even one bank has a refresh operation in progress. In contrast, with bank-specific indications, the host device can start normal read and write accesses before expiration of the self-refresh exit time with any banks that do not have a refresh operation in progress.

For the example scenarios of FIGS. 8-10, three internal refreshes are depicted. A self-refresh operation 306-2 is not in progress when the self-refresh exit command 410 is processed. In contrast, two memory banks have a refresh operation in progress. These two memory banks are: bank group 2, memory bank 3 (BG2, MB3) and bank group 3, memory bank 2 (BG3, MB2). The memory bank 3 of bank group 2 corresponds to the self-refresh operation 306-11. The memory bank 2 of bank group 3 corresponds to the self-refresh operation 306-12. For these example scenarios, the self-refresh operation 306-11 and the self-refresh operation 306-12 overlap in time at least partially. However, the start of the self-refresh operations are staggered such that the self-refresh operation 306-11 starts before the self-refresh operation 306-12 starts. In other words, the self-refresh operation 306-12 starts after the self-refresh operation 306-11 has started but before the self-refresh operation 306-11 has completed.

A self-refresh status indication for each memory bank of multiple memory banks is set forth in a table 802. The table 802 matches the example 16-bank memory bank architecture of FIG. 3; however, the principles are applicable to architectures with a different quantity of memory banks or bank groups. With the 16 banks distributed as four memory banks per bank group, the table 802 is a four-by-four matrix or grid of four bank groups extending horizontally and four memory banks extending vertically. The self-refresh status indications for the memory banks with a zero (“0”) value do not have a refresh operation in progress when processing the self-refresh exit command 410. On the other hand, the self-refresh status indications for the memory banks with a one (“1”) value do have a refresh operation in progress when processing the self-refresh exit command 410. Thus, the bank group 2, memory bank 3 self-refresh status indication is a “1,” and the bank group 3, memory bank 2 self-refresh status indication is also a “1.”

The memory device 108 can maintain the self-refresh status indications of the table 802 during the self-refresh mode or create them in response to the self-refresh exit command 410. Regardless, the values may be stored in at least one register 308 (of FIG. 3) of the memory device 108. By way of example only, the at least one register 308 may comprise a mode register of the memory device 108. In some cases, the memory device 108 can expose the values of the self-refresh status indications of the table 802 to a host device 104, including to a memory controller 114 thereof (or a separate memory controller 114). For instance, the memory device 108 can transmit one or more of the self-refresh status indications in response to a request for such indications, such as a provide-indication command 504 (e.g., of FIGS. 5, 7-1, 7-2, 9, and 10).

FIG. 8 depicts a timing diagram 800 that illustrates example exit schemes from a self-refresh mode in which a memory device provides a bank-specific self-refresh status indication based on a self-refresh exit command 410. In these example exit schemes, the memory device transmits at least one self-refresh status indication 122 after receiving the self-refresh exit command 410 without waiting for (or needing) a request for the indication, such as a provide-indication command 504.

In example implementations, the memory device 108 drives the self-refresh status indication 122 on the DQ bus within a prescribed time period that elapses relative to the self-refresh exit command 410. In some cases, the memory device presents the self-refresh status indication 122 within a read latency timing after the self-refresh exit command of “tXSR_RL.” This duration may be adjustable, and the memory device may enable another device (e.g., a host device or testing device) to specify the adjustable duration, such as through a mode-register write (MRW) command or blowing one or more fuses.

As depicted in FIG. 8, the self-refresh status indication 122 provides an indication for individual memory banks automatically—instead of the providing being contingent on receiving a request for the indication. For instance, the memory device can transmit the self-refresh status indication 122 based on the self-refresh exit command and responsive to a time period that elapses relative to the self-refresh exit command—without waiting for another external command from the host device. In this example, there are 16 values respectively indicative of the 16 memory banks. The values can be presented on the DQ bus in any manner, such as eight values at a time for an eight-bit-wide bus. In this example, the at least one self-refresh status indication 122 indicates that two memory banks (BG2, MB3 and BG3, MB2) have self-refresh operations in progress. Thus, the host device cannot activate rows in these two indicated memory banks until expiration of the self-refresh exit time as indicated at 804.

The other 14 memory banks, however, are available for activation during the self-refresh exit operational phase 404-2. The host device can determine this availability after analyzing the at least one self-refresh status indication 122 and can then start sending read or write requests to the memory device as indicated at 804. Two illustrated example row activation commands target the memory bank 1 of the bank group 1 (“BG1, MB1”) and the memory bank 4 of the bank group 3 (“BG3, MB4”). After expiration of the self-refresh exit time (tXSR), all array operations are legal again as indicated at 806. Thus, the host device can also send activation commands to those bank(s) that had self-refresh operations in progress, such as the memory bank 2 of the bank group 3 (“BG3, MB2”).

FIG. 9 depicts a timing diagram 900 that illustrates example exit schemes from a self-refresh mode in which a memory device provides a bank-specific self-refresh status indication 122 based on a self-refresh exit command 410 and responsive to a mode-register read (MRR) command 504 requesting the indication. In some cases, the host device issues the request 504 with a read duration timing after the self-request exit command of “tXSR_RD.” In example implementations, the host device issues, and the memory device receives, a first MRR command 504-1 (“MRR Cmd” 504-1). In response to the first MRR command 504-1, the memory device transmits at least one first self-refresh status indication 122-1. In the illustrated example of FIG. 9, each MRR command requests the reading of one mode register, which has eight bits. Because each mode register includes eight bits, the memory device devotes two mode registers 308-1 and 308-2 to storing the 16 values for the self-refresh status indications. Accordingly, the memory device transmits the eight values from the first mode register 308-1 as the first at least one self-refresh status indication 122-1, which provides individualized indications for 8 of the 16 memory banks.

After a mode-register-read duration that transpires after the self-request exit command of “tXSR_MRR,” the host device issues, and the memory device receives, a second MRR command 504-2 (“MRR Cmd” 504-2). In response to the second MRR command 504-2, the memory device transmits at least one second self-refresh status indication 122-2. The memory device transmits the eight values from the second mode register 308-2 as the second at least one self-refresh status indication 122-2, which provides individualized indications for the other eight memory banks.

Similar to the example scenarios of FIG. 8, with the example scenarios of FIG. 9, activation on banks that had in-progress refresh operations when the self-refresh exit command 410 is processed are illegal until expiration of the self-refresh exit time, as indicated at 904. Activations on other banks, however, are legal at 904. Thus, the host device has 14 memory bank options, such as the memory bank 1 of the bank group 1 (“BG1, MB1”), for starting read and write operations earlier than with memory systems that lack self-refresh status indications. At 906, activations and normal read/write accesses are legal on all memory banks of the memory array. More specifically, after expiration of the self-refresh exit time tXSR, the self-refresh mode and procedures to terminate the self-refresh mode in the self-refresh exit operational phase 404-2 no longer constrain the selection of array operations by the host device.

FIG. 10 depicts a timing diagram 1000 that illustrates example exit schemes from a self-refresh mode in which a memory device provides a bank-specific self-refresh status indication 122 based on a self-refresh exit command 410 and responsive to a multi-purpose command 504 (“MP Cmd 504”) requesting the indication. The example exit schemes of FIG. 10 are similar to the example exit schemes of FIG. 9. Instead of employing an MRR command, however, the system utilizes a multipurpose command (MPC). Thus, the provide-indication command 504 can be realized with an MPC.

In example implementations, the host device issues, and the memory device receives, a multipurpose command 504 that causes the memory device to provide at least one self-refresh status indication 122. In other words, in response to the multipurpose command 504, the memory device transmits at least one self-refresh status indication 122, which provides indications on a per-bank basis. With an MPC, the memory device can be configured to transmit all bits of the self-refresh status indications responsive to, for instance, a single MPC. A single MPC can trigger transmission of all bits even if the memory device needs or otherwise elects to use multiple transmissions over the DQ bus and even if the number of bits for the indication exceeds the size of each mode register. Thus, using an MPC can be faster or can involve less command bus traffic as compared to using multiple MRR commands, including by being both faster and involving less command bus traffic in accordance with a permitted herein, but optional, interpretation of the word “or” as an “inclusive or.”

Similar to the example scenarios of FIG. 9, with the example scenarios of FIG. 10, activation on banks that had in-progress refresh operations when the self-refresh exit command 410 is processed are illegal until expiration of the self-refresh exit time, as indicated at 904. Activations on other banks, however, are legal at 904. Thus, the host device has 14 memory bank options, such as the memory bank 2 of the bank group 2 (“BG2, MB2”), for starting read and write operations earlier than with memory systems that lack self-refresh status indications. At 906, after expiration of the self-refresh exit time tXSR, activations and normal read/write accesses are legal on all memory banks of the memory array. More specifically, the self-refresh mode and procedures to terminate the self-refresh mode in the self-refresh exit operational phase 404-2 no longer constrain the bank selection of array operations by the host device.

### Example Methods

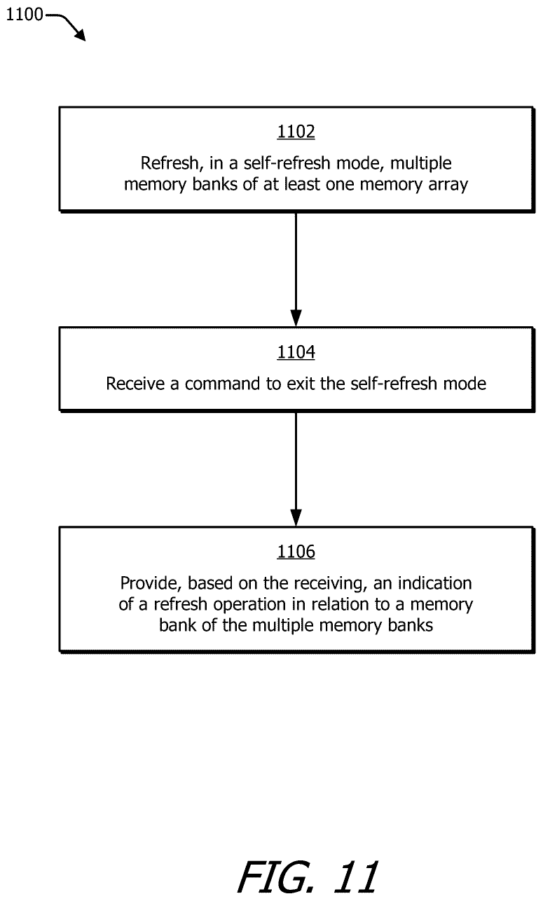

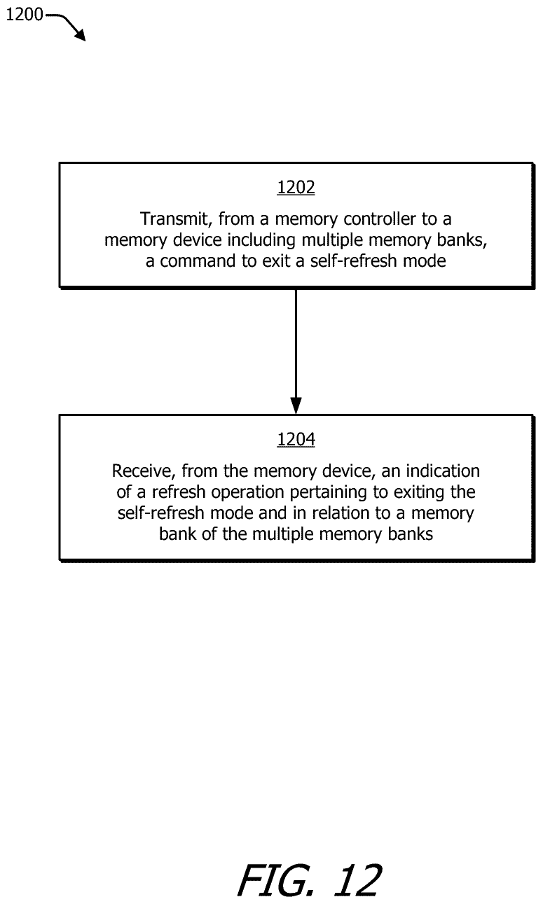

This subsection describes example methods for implementing self-refresh status indication for self-refresh exit with reference to the flow diagrams of FIGS. 11 and 12. These descriptions may also refer to components, entities, and other aspects depicted in FIGS. 1 to 10, but by way of example only. The described methods are not necessarily limited to performance by one entity or multiple entities operating on one device. In particular, but by way of example only, the description of FIG. 5 provides multiple examples for one or more commands, responses, messages, operations, and so forth.

FIG. 11 illustrates a flow diagram 1100, which includes operations 1102-1106, for implementing aspects of self-refresh status indications for self-refresh exit for a memory device. In aspects, operations of the method 1100 can be implemented by refresh logic 120 in conjunction with an interface 206 of a memory device 108 as described with reference to FIGS. 1 to 10.

At block 1102, a memory device refreshes, in a self-refresh mode, multiple memory banks of at least one memory array. For example, refresh logic 120 can refresh, in a self-refresh mode, multiple memory banks 302-1 to 302-X (where “X” represents an integer greater than one) of at least one memory array 204. To do so, the refresh logic 120 may refresh each bank, or row thereof, at a given frequency that is determined using a timer that is internal to the memory device 108.

At block 1104, the memory device receives a command to exit the self-refresh mode. For example, the refresh logic 120 can receive a command 410 to exit the self-refresh mode. Processing a self-refresh exit command 410, as received from a host device 104, may start the timing for a self-refresh exit time.

At block 1106, the memory device provides, based on the receiving, an indication of a refresh operation in relation to a memory bank of the multiple memory banks. For example, the refresh logic 120 can provide, based on the receiving of the self-refresh exit command 410, an indication 122 of a refresh operation 306 in relation to a memory bank 302 of the multiple memory banks 302-1 to 302-X. For instance, the refresh logic 120 may transmit to the host device 104 at least one self-refresh status indication 122, which can include one or more bits. The self-refresh status indication 122 may relate to at least one memory bank 302 by representing whether the memory bank 302 had a self-refresh operation 306 in progress when the self-refresh exit command 410 is being processed. In some cases, a single bit may represent a Boolean value for an entire memory device, memory die, or memory array. In other cases, each bit of multiple bits can represent an individual memory bank 302 or an individual bank group 304 of a memory array 204.

With respect to at least a portion (e.g., a memory bank 302) of the memory array 204, the memory device 108 can start processing an external memory access command from the host device 104 before expiration of the self-refresh exit time if the portion was not undergoing a self-refresh operation 306 when the self-refresh exit command 410 was processed. For example, the array control logic 210 can implement an activate command (ACT command) directed to a row of a memory bank 302 of the multiple memory banks 302-1 to 302-X during a self-refresh exit operational phase 404-2.

FIG. 12 illustrates a flow diagram 1200, which includes operations 1202 and 1204, for implementing aspects of self-refresh status indications for self-refresh exit for a host device. In aspects, operations of the method 1200 can be implemented by refresh logic 118 in conjunction with an interface 506 of a host device 104 as described with reference to FIGS. 1 to 10.

At block 1202, a host device transmits, from a memory controller to a memory device including multiple memory banks, a command to exit a self-refresh mode. For example, refresh logic 118 can transmit, from a memory controller 114 to a memory device 108 that includes multiple memory banks 302-1 to 302-X, a command 410 to exit a self-refresh mode. For instance, after previously transmitting a self-refresh entry command 502 to cause the memory device 108 to enter a self-refresh mode, the refresh logic 118 may transmit the self-refresh exit command 410 to the memory device 108 to cause the memory device 108 to start exiting the self-refresh mode and to start a timer for the self-refresh exit time. Initially, during a self-refresh exit operational phase 404-2 for the memory device 108, the host device 104 is not permitted to send normal read or write commands.

At block 1204, the host device receives, from the memory device, an indication of a refresh operation pertaining to exiting the self-refresh mode and in relation to a memory bank of the multiple memory banks. For example, the refresh logic 118 can receive, from the memory device 108, an indication 122 of a refresh operation 306 pertaining to exiting the self-refresh mode (e.g., pertaining to a transition between a self-refresh operational phase 402-2 and the self-refresh exit operational phase 404-2 or pertaining to issuance of the self-refresh exit command 410) and in relation to a memory bank 302 of the multiple memory banks 302-1 to 302-X. In some cases, the at least one self-refresh status indication 122 may include at least one bit that is indicative of a status of a self-refresh operation 306 in relation to a memory bank 302 of the multiple memory banks 302-1 to 302-X.

The at least one bit can identify a memory bank 302 that is performing a refresh operation or that is not performing a refresh operation responsive to a processing of the self-refresh exit command 410. The memory controller 114 may therefore transmit, prior to expiration of the self-refresh exit time, a read or write operation to the memory device 108 that targets a memory bank 302 that was not performing a refresh operation when the self-refresh exit procedure was initiated.

For the figures and operations described above, the orders in which the operations are shown and/or described are not intended to be construed as a limitation. Any number or combination of the described process operations can be combined or rearranged in any order to implement a given method or an alternative method. Operations may also be omitted from or added to the described methods. Further, described operations can be implemented in fully or partially overlapping manners.

Aspects of these methods may be implemented in, for example, hardware (e.g., fixed-logic circuitry or a processor in conjunction with a memory), firmware, software, or some combination thereof. The methods may be realized using one or more of the apparatuses or components shown in FIGS. 1 to 10, the components of which may be further divided, combined, rearranged, and so on. The devices and components of these figures generally represent hardware, such as electronic devices, packaged modules, IC chips, or circuits; firmware or the actions thereof; software; or a combination thereof. Thus, these figures illustrate some of the many possible systems or apparatuses capable of implementing the described methods.

Computer-readable media includes both non-transitory computer storage media and communication media including any medium that facilitates transfer of a computer program (e.g., an application) or data from one entity to another. Non-transitory computer storage media can be any available medium accessible by a computer, such as RAM, ROM, Flash, EEPROM, optical media, and magnetic media.

In the following, various examples for implementing aspects of self-refresh status indication for self-refresh exit are described:

Example 1: An apparatus comprising:
a memory device comprising:
   at least one memory array comprising multiple memory banks; and
   refresh logic coupled to the at least one memory array, the refresh logic configured to:
      refresh the multiple memory banks in a self-refresh mode;
      receive a command to exit the self-refresh mode; and
      provide, based on the command to exit the self-refresh mode, an indication of a refresh operation in relation to a memory bank of the multiple memory banks.

Example 2: The apparatus of example 1 or any other example, wherein:
the indication of the refresh operation in relation to the memory bank of the multiple memory banks comprises an indication that the refresh operation is in progress on the memory bank when the command to exit the self-refresh mode is being processed.

Example 3: The apparatus of example 2 or any other example, wherein the command to exit the self-refresh mode is being processed comprises at least one of:
the memory device is receiving the command;
the refresh logic is receiving the command;
the refresh logic is decoding the command; or
the refresh logic is performing the command.

Example 4: The apparatus of example 2 or any other example, wherein the refresh operation is in progress on the memory bank comprises at least one of:
the refresh logic has activated a row of the memory bank for the refresh operation; or
the refresh logic has scheduled a row of the memory bank for the refresh operation.

Example 5: The apparatus of example 1 or any other example, wherein:
the memory device comprises an interface configured to be coupled to a host device; and
the refresh logic is configured to receive the command to exit the self-refresh mode from the host device via the interface.

Example 6: The apparatus of example 1 or any other example, wherein:
the indication of the refresh operation in relation to the memory bank of the multiple memory banks comprises a Boolean indication that one or more memory banks of the multiple memory banks has a refresh operation in progress or that no memory bank of the multiple memory banks has a refresh operation in progress.

Example 7: The apparatus of example 6 or any other example, wherein the memory device comprises:
array control logic coupled to the at least one memory array, the array control logic configured to:
   prevent access to the at least one memory array during a self-refresh exit time responsive to the Boolean indication being indicative that the one or more memory banks of the multiple memory banks has a refresh operation in progress; and
   permit access to the at least one memory array during the self-refresh exit time responsive to the Boolean indication being indicative that no memory bank of the multiple memory banks has a refresh operation in progress.

Example 8: The apparatus of example 1 or any other example, wherein:
the indication of the refresh operation in relation to the memory bank of the multiple memory banks comprises an identification of a subset of the multiple memory banks, the subset having the refresh operation in progress.

Example 9: The apparatus of example 8 or any other example, wherein:
the identification of the subset of the multiple memory banks that has the refresh operation in progress comprises at least one individual memory bank of the multiple memory banks.

Example 10: The apparatus of example 8 or any other example, wherein:
the identification of the subset of the multiple memory banks that has the refresh operation in progress comprises at least one individual bank group of the multiple memory banks.

Example 11: The apparatus of example 8 or any other example, wherein:
the memory device further comprises one or more registers comprising multiple bits configured to represent the identification of the subset of the multiple memory banks.

Example 12: The apparatus of example 11 or any other example, wherein:
each respective bit of the multiple bits corresponds to a respective identification of a respective part of the subset of the multiple memory banks; and
the refresh logic is configured to store a value in a bit of the multiple bits based on whether a refresh operation is in progress for the respective part of the subset of the multiple memory banks with regard to receipt of the command to exit the self-refresh mode.

Example 13: The apparatus of example 1 or any other example, wherein:
the refresh logic is configured to provide the indication of the refresh operation in relation to the memory bank of the multiple memory banks by transmitting the indication of the refresh operation based on the command to exit the self-refresh mode.

Example 14: The apparatus of example 13 or any other example, wherein:
the refresh logic is configured to transmit the indication of the refresh operation based on the command to exit the self-refresh mode and before receiving an external command.

Example 15: The apparatus of example 13 or any other example, wherein:
the refresh logic is configured to transmit the indication of the refresh operation within a predetermined time period that starts elapsing based on the command to exit the self-refresh mode.

Example 16: The apparatus of example 13 or any other example, wherein:
the refresh logic is configured to transmit the indication of the refresh operation on a data bus that is coupled to a host device.

Example 17: The apparatus of example 1 or any other example, wherein:
the refresh logic is configured to provide the indication of the refresh operation in relation to the memory bank of the multiple memory banks based on the command to exit the self-refresh mode and responsive to an external command.

Example 18: The apparatus of example 17 or any other example, wherein the refresh logic is configured to:
receive the external command, the external command comprising a mode-register read command; and
provide the indication of the refresh operation in relation to the memory bank of the multiple memory banks by transmitting the indication of the refresh operation responsive to the mode-register read command.

Example 19: The apparatus of example 18 or any other example, wherein the refresh logic is configured to:
receive multiple mode-register read commands;
read multiple values from multiple mode registers; and
provide the indication of the refresh operation in relation to the memory bank of the multiple memory banks by transmitting multiple indications of a refresh operation responsive to the multiple mode-register read commands and based on the multiple values read from the multiple mode registers.

Example 20: The apparatus of example 17 or any other example, wherein the refresh logic is configured to:
receive the external command, the external command comprising a multipurpose command; and
provide the indication of the refresh operation in relation to the memory bank of the multiple memory banks by transmitting the indication of the refresh operation responsive to the multipurpose command.

Example 21: The apparatus of example 1 or any other example, wherein:
the indication of the refresh operation in relation to the memory bank of the multiple memory banks is indicative that the memory bank of the multiple memory banks is not performing the refresh operation; and
the memory device comprises array control logic coupled to the at least one memory array, the array control logic configured to at least start processing, during a self-refresh exit time, an external memory access command directed to at least one memory bank of the multiple memory banks.

Example 22: The apparatus of example 21 or any other example, wherein:
the array control logic is configured to at least start processing the external memory access command by implementing an activate command directed to a row of the at least one memory bank of the multiple memory banks.

Example 23: The apparatus of example 1 or any other example, wherein:
the indication of the refresh operation in relation to the memory bank of the multiple memory banks is indicative that the memory bank of the multiple memory banks is performing the refresh operation; and
the memory device comprises array control logic coupled to the at least one memory array, the array control logic configured to at least start processing, during a self-refresh exit time, an external memory access command directed to another memory bank of the multiple memory banks.

Example 24: A method for a memory device or any other example, the method comprising:
refreshing, in a self-refresh mode, multiple memory banks of at least one memory array;
receiving a command to exit the self-refresh mode; and
providing, based on the receiving, an indication of a refresh operation in relation to a memory bank of the multiple memory banks.

Example 25: The method of example 24 or any other example, further comprising:
receiving a command to transmit the indication of the refresh operation,
wherein the providing comprises transmitting the indication of the refresh operation in response to the receiving of the command to transmit the indication of the refresh operation.

Example 26: An apparatus comprising:
a memory controller comprising:
   an interface configured to be coupled to a memory device comprising multiple memory banks; and
   refresh logic coupled to the interface, the refresh logic configured to:
      transmit, from the interface, a command to exit a self-refresh mode; and
      receive, via the interface, an indication of a refresh operation pertaining to exiting the self-refresh mode and in relation to a memory bank of the multiple memory banks.

Example 27: The apparatus of example 26 or any other example, wherein:
the indication of the refresh operation pertaining to exiting the self-refresh mode and in relation to the memory bank of the multiple memory banks comprises an indication that the refresh operation is in progress on the memory bank when the command to exit the self-refresh mode is being processed by the memory device.

Example 28: A method for a host device, the method comprising:
transmitting, from a memory controller to a memory device comprising multiple memory banks, a command to exit a self-refresh mode; and
receiving, from the memory device, an indication of a refresh operation pertaining to exiting the self-refresh mode and in relation to a memory bank of the multiple memory banks.

Unless context dictates otherwise, use herein of the word “or” may be considered use of an “inclusive or,” or a term that permits inclusion or application of one or more items that are linked by the word “or” (e.g., a phrase “A or B” may be interpreted as permitting just “A,” as permitting just “B,” or as permitting both “A” and “B”). Also, as used herein, a phrase referring to “at least one of” a list of items refers to any combination of those items, including single members. For instance, “at least one of a, b, or c” can cover a, b, c, a-b, a-c, b-c, and a-b-c, as well as any combination with multiples of the same element (e.g., a-a, a-a-a, a-a-b, a-a-c, a-b-b, a-c-c, b-b, b-b-b, b-b-c, c-c, and c-c-c, or any other ordering of a, b, and c). Further, items represented in the accompanying figures and terms discussed herein may be indicative of one or more items or terms, and thus reference may be made interchangeably to single or plural forms of the items and terms in this written description.

### Conclusion

Although aspects of implementing self-refresh status indication for self-refresh exit have been described in language specific to certain features and/or methods, the subject of the appended claims is not necessarily limited to the specific features or methods described. Rather, the specific features and methods are disclosed as a variety of example implementations for self-refresh status indication for self-refresh exit.

What is claimed is:

1. An apparatus comprising:
a memory device comprising:
at least one memory array comprising multiple memory banks; and
refresh logic coupled to the at least one memory array, the refresh logic configured to:
refresh the multiple memory banks in a self-refresh mode;
receive a command to exit the self-refresh mode; and
provide, based on the command to exit the self-refresh mode, an indication of a refresh operation in relation to a memory bank of the multiple memory banks.

2. The apparatus of claim 1, wherein:
the indication of the refresh operation in relation to the memory bank of the multiple memory banks comprises an indication that the refresh operation is in progress on the memory bank when the command to exit the self-refresh mode is being processed.

3. The apparatus of claim 1, wherein:
the indication of the refresh operation in relation to the memory bank of the multiple memory banks comprises a Boolean indication that one or more memory banks of the multiple memory banks has a refresh operation in progress or that no memory bank of the multiple memory banks has a refresh operation in progress.

4. The apparatus of claim 3, wherein the memory device comprises:
array control logic coupled to the at least one memory array, the array control logic configured to:
prevent access to the at least one memory array during a self-refresh exit time responsive to the Boolean indication being indicative that the one or more memory banks of the multiple memory banks has a refresh operation in progress; and
permit access to the at least one memory array during the self-refresh exit time responsive to the Boolean indication being indicative that no memory bank of the multiple memory banks has a refresh operation in progress.

5. The apparatus of claim 1, wherein:
the indication of the refresh operation in relation to the memory bank of the multiple memory banks comprises an identification of a subset of the multiple memory banks, the subset having the refresh operation in progress.

6. The apparatus of claim 5, wherein:
the identification of the subset of the multiple memory banks that has the refresh operation in progress comprises at least one individual memory bank of the multiple memory banks.

7. The apparatus of claim 5, wherein:
the identification of the subset of the multiple memory banks that has the refresh operation in progress comprises at least one individual bank group of the multiple memory banks.

8. The apparatus of claim 5, wherein:
the memory device further comprises one or more registers comprising multiple bits configured to represent the identification of the subset of the multiple memory banks.

9. The apparatus of claim 8, wherein:
each respective bit of the multiple bits corresponds to a respective identification of a respective part of the subset of the multiple memory banks; and
the refresh logic is configured to store a value in a bit of the multiple bits based on whether a refresh operation is in progress for the respective part of the subset of the multiple memory banks with regard to receipt of the command to exit the self-refresh mode.

10. The apparatus of claim 1, wherein:
the refresh logic is configured to provide the indication of the refresh operation in relation to the memory bank of the multiple memory banks by transmitting the indication of the refresh operation based on the command to exit the self-refresh mode.

11. The apparatus of claim 10, wherein:
the refresh logic is configured to transmit the indication of the refresh operation based on the command to exit the self-refresh mode and before receiving an external command.

12. The apparatus of claim 10, wherein:
the refresh logic is configured to transmit the indication of the refresh operation within a predetermined time period that starts elapsing based on the command to exit the self-refresh mode.

13. The apparatus of claim 1, wherein:
the refresh logic is configured to provide the indication of the refresh operation in relation to the memory bank of the multiple memory banks based on the command to exit the self-refresh mode and responsive to an external command.

14. The apparatus of claim 13, wherein the refresh logic is configured to:
receive the external command, the external command comprising a mode-register read command; and
provide the indication of the refresh operation in relation to the memory bank of the multiple memory banks by transmitting the indication of the refresh operation responsive to the mode-register read command.

15. The apparatus of claim 13, wherein the refresh logic is configured to:
receive the external command, the external command comprising a multipurpose command; and
provide the indication of the refresh operation in relation to the memory bank of the multiple memory banks by transmitting the indication of the refresh operation responsive to the multipurpose command.

16. The apparatus of claim 1, wherein:
the indication of the refresh operation in relation to the memory bank of the multiple memory banks is indicative that the memory bank of the multiple memory banks is not performing the refresh operation; and
the memory device comprises array control logic coupled to the at least one memory array, the array control logic configured to at least start processing, during a self-refresh exit time, an external memory access command directed to at least one memory bank of the multiple memory banks.

17. The apparatus of claim 1, wherein:
the indication of the refresh operation in relation to the memory bank of the multiple memory banks is indicative that the memory bank of the multiple memory banks is performing the refresh operation; and
the memory device comprises array control logic coupled to the at least one memory array, the array control logic configured to at least start processing, during a self-refresh exit time, an external memory access command directed to another memory bank of the multiple memory banks.

18. A method for a memory device, the method comprising:
refreshing, in a self-refresh mode, multiple memory banks of at least one memory array;
receiving a command to exit the self-refresh mode; and
providing, based on the receiving, an indication of a refresh operation in relation to a memory bank of the multiple memory banks.

19. The method of claim 18, further comprising:
receiving a command to transmit the indication of the refresh operation,
wherein the providing comprises transmitting the indication of the refresh operation in response to the receiving of the command to transmit the indication of the refresh operation.

20. An apparatus comprising:
a memory controller comprising:
an interface configured to be coupled to a memory device comprising multiple memory banks; and
refresh logic coupled to the interface, the refresh logic configured to:
transmit, from the interface, a command to exit a self-refresh mode; and
receive, via the interface, an indication of a refresh operation pertaining to exiting the self-refresh mode and in relation to a memory bank of the multiple memory banks.
